(19) United States
(12) Patent Application Publication
(10) Pub. No.: US 2020/0292206 A1
(43) Pub. Date: Sep. 17, 2020

(54) CHARGING FIBER, CHARGING FILTER, SUBSTANCE ATTRACTING MATERIAL, AND AIR PURIFIER

(71) Applicant: Murata Manufacturing Co., Ltd., Nagaokakyo-shi (JP)

(72) Inventors: Daiji Tamakura, Nagaokakyo-shi (JP); Masamichi Ando, Nagaokakyo-shi (JP); Takafumi Inoue, Nagaokakyo-shi (JP); Kenichiro Takumi, Nagaokakyo-shi (JP)

(21) Appl. No.: 16/891,144

(22) Filed: Jun. 3, 2020

Related U.S. Application Data
(63) Continuation of application No. PCT/JP2019/013140, filed on Mar. 27, 2019.

(30) Foreign Application Priority Data
Mar. 28, 2018 (JP) 2018-062194

(51) Int. Cl. F24F 13/28; H01L 41/08; B01D 39/20

(52) U.S. Cl. CPC F24F 13/28; B01D 39/2082; H01L 41/082

(57) ABSTRACT

A charging fiber arrangement that includes a pair of adjacent polarization generation fibers that each generate a positive potential or a negative potential on a surface thereof by input of external energy. The pair of adjacent polarization generation fibers are arranged to positively charge a substance passing between the pair of adjacent polarization generation fibers by the positive potential, or negatively charge the substance passing between the pair of adjacent polarization generation fibers by the negative potential.

### CROSS REFERENCE TO RELATED APPLICATIONS

The present application is a continuation of International application No. PCT/JP2019/013140, filed Mar. 27, 2019, which claims priority to Japanese Patent Application No. 2018-062194, filed Mar. 28, 2018, the entire contents of each of which are incorporated herein by reference.

### FIELD OF THE INVENTION

The present invention relates to a charging fiber for charging a substance, a charging filter including the charging fiber, a substance attracting material including the charging filter and an attraction filter, and an air purifier.

### BACKGROUND OF THE INVENTION

Patent Document 1 discloses an air purifier which charges a substance by corona discharge, and then attracts the charged substance by the electrostatic force of an electret filter.

Patent Document 1: Japanese Patent Application Laid-Open No. H5-7797

### SUMMARY OF THE INVENTION

However, the air purifier of Patent Document 1 needs to be provided with a large unit for corona discharge.

Therefore, an object of the present invention is to provide a charging fiber, a charging filter, a substance attracting material, and an air purifier that does not require a large unit for corona discharge.

A charging fiber arrangement of the present invention includes a pair of adjacent polarization generation fibers that each generates a positive potential or a negative potential on the surface thereof by input of external energy. The pair of adjacent polarization generation fibers are arranged to positively charge a substance passing between the pair of adjacent polarization generation fibers by the positive potential, or negatively charge the substance passing between the pair of adjacent polarization generation fiber by the negative potential.

As the polarization generation fiber that generates polarization by external energy, there are a substance having a piezoelectric effect (poly lactic acid (PLA)), a substance having a photoelectric effect, a substance having a pyroelectric effect (for example, polyvinylidene difluoride (PVDF)), a substance that generates polarization due to a chemical change, and the like. With the polarization generation fiber formed of such a substance, it is possible to charge a substance without requiring a large unit for corona discharge.

Further, the air purifier of Patent Document 1 needs to consume power for corona discharge. However, in a case where the polarization generation fiber is formed of a piezoelectric fiber, the piezoelectric fiber extends and contracts due to the air flow, so that the polarization generation fiber does not require electric power to generate a positive potential or a negative potential on the surface.

According to the invention, it is possible to charge a substance without requiring a large unit for corona discharge.

### BRIEF EXPLANATION OF THE DRAWINGS

FIG. 1 is a perspective view of a substance attracting material 100 including a charging filter 5 and an attraction filter 20.

FIG. 2(A) is a diagram illustrating a configuration of a piezoelectric thread 1, and FIG. 2(B) is a plan view of a piezoelectric film 10.

FIG. 3(A) and FIG. 3(B) are diagrams each illustrating a relationship among a uniaxial stretching direction of polylactic acid, an electric field direction, and deformation of the piezoelectric film 10.

FIG. 4 is a diagram illustrating the piezoelectric thread 1 when an external force is applied to the piezoelectric thread 1.

FIG. 5 is a diagram illustrating a configuration of a piezoelectric thread 3.

FIG. 6 is a diagram illustrating a configuration of a Z thread (covering thread) 1A.

FIG. 7 is a partial sectional view of the charging filter 5 and the attraction filter 20.

FIG. 8 is a sectional view of the charging filter 5.

FIG. 9(A) is a sectional view illustrating a state where the attraction filter 20 has attracted a substance 50 charged to a positive potential, FIG. 9(B) is a sectional view illustrating a state where the potential of the surface of the attraction filter 20 has become positive at a certain portion, and FIG. 9(C) is a sectional view illustrating a state where the potential of the surface of the attraction filter 20 has become negative again.

FIG. 10 is a partial sectional view of a first charging filter 5A, a second charging filter 5B, and the attraction filter 20.

FIG. 11 is a partial sectional view of a piezoelectric thread 1A, which includes an electrode 71 and the attraction filter 20.

FIG. 12(A) is a plan view of a charging filter 5C according to Modification Example 1, and FIG. 12(B) is a sectional view of the charging filter 5C.

FIG. 13(A) is a perspective view of a charging filter 5D according to Modification Example 2, and FIG. 13(B) is a sectional view of the charging filter 5D.

FIG. 14(A) is a plan view of a piezoelectric sheet 1D as viewed in plan, and FIG. 14(B) is a rear view.

FIG. 15 is a partial sectional view of a charging filter 51 and the attraction filter 20.

### DETAILED DESCRIPTION OF THE INVENTION

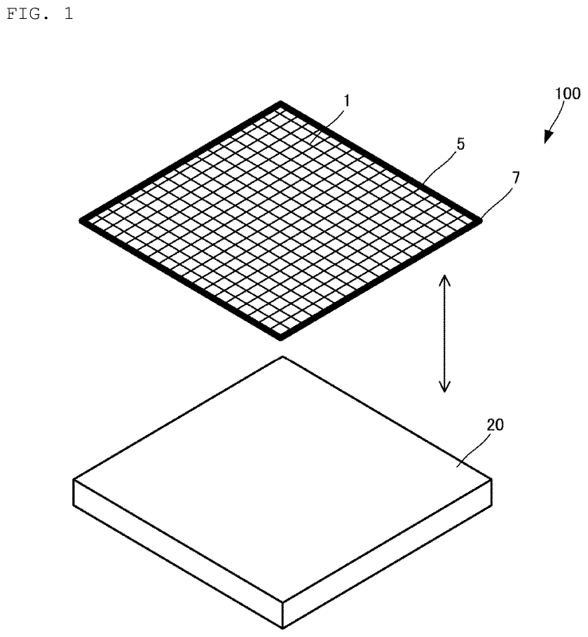

FIG. 1 is a perspective view of a substance attracting material 100 including a charging filter 5 and an attraction filter 20. The substance attracting material 100 is used, for example, as a filter of an air purifier. The charging filter 5 includes piezoelectric threads 1 and a frame 7. piezoelectric threads 1 are fixed to the frame 7 at both ends in an axial direction. piezoelectric threads 1 are arranged in a first direction (longitudinal direction) and a second direction (lateral direction) orthogonal to the first direction, and are arranged in a lattice shape. Note that the arrangement of the piezoelectric threads 1 is not limited to the form illustrated in FIG. 1. The piezoelectric threads 1 may be arranged, for example, in an oblique direction.

The attraction filter 20 is, for example, an electret high-efficiency particulate air (HEPA) filter. The surface of the attraction filter 20 is polarized to a negative polarity or a positive polarity.

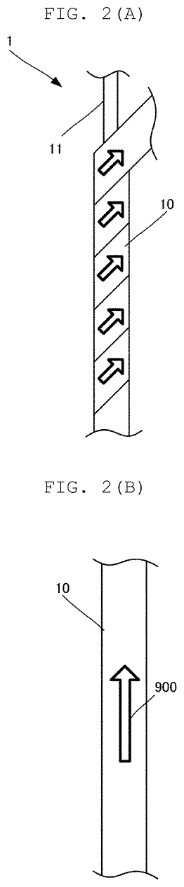

FIG. 2(A) is a partially exploded view illustrating a configuration of a piezoelectric thread 1, and FIG. 2(B) is a plan view of a piezoelectric film 10. The piezoelectric thread 1 is an example of a polarization generation fiber that generates polarization through external energy.

The piezoelectric thread 1 is formed by helically winding the piezoelectric film 10 around a core thread 11. However, the core thread 11 is not an essential component. Even without the core thread 11, a piezoelectric thread (wound thread) can be obtained by helically winding the piezoelectric film 10. In the case where there is no core thread 11, the wound thread is a hollow thread. Further, it is possible to increase strength by impregnating the wound thread itself with adhesive.

The piezoelectric film 10 is made of, for example, a piezoelectric polymer. There are piezoelectric polymers having pyroelectricity and a piezoelectric polymer having no pyroelectricity. For example, polyvinylidene difluoride (PVDF) has piezoelectricity and pyroelectricity, and is polarized even when the temperature changes.

Polylactic acid (PLA) is a piezoelectric polymer having no pyroelectricity. Polylactic acid generates piezoelectricity by being uniaxially stretched. Polylactic acid includes PLLA in which an L-form monomer is polymerized and PDLA in which a D-form monomer is polymerized.

A chiral polymer such as polylactic acid has a main chain having a helical structure. The chiral polymer has piezoelectricity when the chiral polymer is uniaxially stretched so that the molecules are oriented. When a thickness direction is defined as a first axis, a stretching direction 900 is defined as a third axis, and a direction orthogonal to both the first axis and the third axis is defined as a second axis, the piezoelectric film 10 made of uniaxially stretched polylactic acid has tensor components of d14 and d25 as piezoelectric strain constants. Therefore, polylactic acid generates polarization in the case where strain occurs in a direction at 45 degrees with respect to the uniaxially stretched direction.

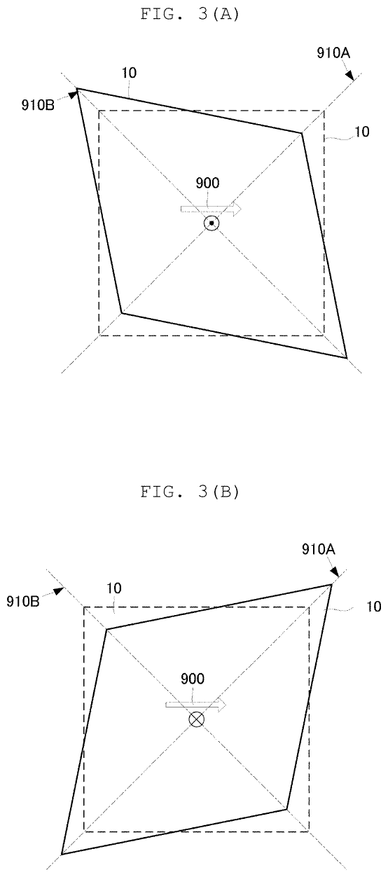

FIG. 3(A) and FIG. 3(B) are diagrams each illustrating a relationship among a uniaxial stretching direction of polylactic acid, an electric field direction, and deformation of the piezoelectric film 10. As illustrated in FIG. 3(A), when the piezoelectric film 10 contracts in a direction of a first diagonal line 910A and extends in a direction of a second diagonal line 910B orthogonal to the first diagonal line 910A, an electric field is generated in a direction from the rear side to the front side of the paper. That is, the piezoelectric film 10 generates a negative potential on the front side of the paper. As illustrated in FIG. 3(B), when the piezoelectric film 10 extends in the direction of the first diagonal line 910A and contracts in the direction of the second diagonal line 910B, polarization is generated, but the polarity is reversed, and therefore an electric field is generated in a direction from the front side to the rear side of the paper. That is, the piezoelectric film 10 generates a positive potential on the front side of the paper.

Polylactic acid is subjected to orientation processing of molecules by stretching to generate piezoelectricity, and therefore polylactic acid does not need to be subjected to a poling treatment unlike other piezoelectric polymers, such as PVDF or piezoelectric ceramics. The uniaxially stretched polylactic acid has a piezoelectric constant of about 5 to 30 pC/N, and has a very high piezoelectric constant among polymers. Furthermore, the piezoelectric constant of polylactic acid does not fluctuate with time and is extremely stable.

The piezoelectric film 10 is generated by cutting a sheet made of uniaxially stretched polylactic acid as mentioned above into, for example, a width of about 0.5 to 2 mm. The piezoelectric film 10, as illustrated in FIG. 2(B), the major axis direction and the stretching direction 900 coinciding with each other. As illustrated in FIG. 2(A), the piezoelectric film 10 becomes the piezoelectric thread 1 of a leftward wound thread (hereinafter, referred to as a Z thread) twisted leftward with respect to the core thread 11. The stretching direction 900 is inclined 45 degrees to the right in the axial direction of the piezoelectric thread 1.

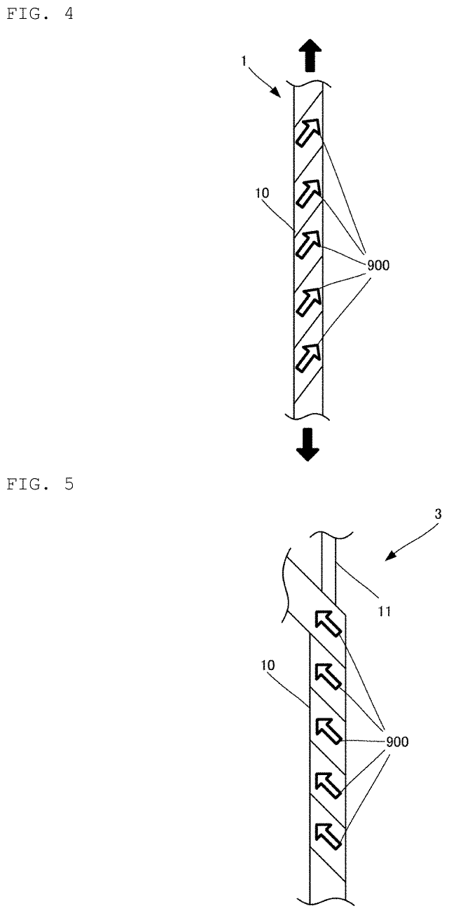

Therefore, as illustrated in FIG. 4, when an external force is applied to the piezoelectric thread 1, the piezoelectric film 10 takes in a state as illustrated in FIG. 3(A), and a positive potential is generated on the surface.

Thus, the piezoelectric thread 1 generates a positive potential on the surface when an external force is applied to the piezoelectric thread 1. Therefore, the piezoelectric thread 1 generates a positive potential through external energy.

On the other hand, FIG. 5 is a diagram illustrating a configuration of a piezoelectric thread 3 of a rightward wound thread (hereinafter, referred to as an S thread). Since the piezoelectric thread 3 is the S thread, the stretching direction 900 is inclined 45 degrees to the left in the axial direction of the piezoelectric thread 3. Therefore, when an external force is applied to the piezoelectric thread 3, the piezoelectric film 10 takes in a state as illustrated in FIG. 3(B), and a negative potential is generated on the surface. Therefore, the piezoelectric thread 3 generates a negative potential through external energy.

Note that the piezoelectric thread is manufactured by any known method. For example, a method of extruding a piezoelectric polymer to form a fiber, a method of melt-spinning a piezoelectric polymer into a fiber, a method of fiberizing a piezoelectric polymer by dry or wet spinning, or a method of fiberizing a piezoelectric polymer by electrostatic spinning, or the like can be adopted.

In addition, as a thread that generates a negative potential on the surface, a Z thread using PDLA is also usable instead of an S thread using PLLA. Further, as a thread that generates a positive potential on the surface, an S thread using PDLA is also usable instead of a Z thread using PLLA.

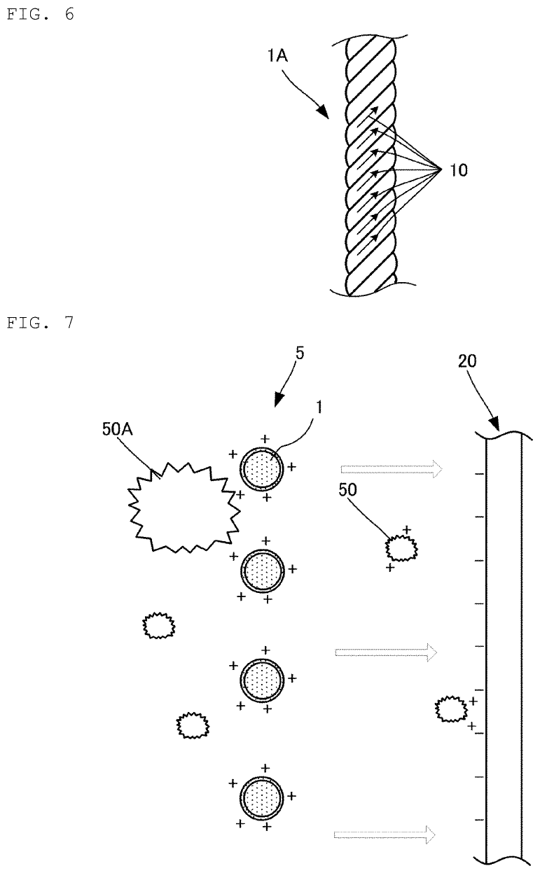

Further, the piezoelectric thread may be made of a piezoelectric body which is ejected from a nozzle and stretched (piezoelectric thread having a circular section). As illustrated in FIG. 6, a Z thread (covering thread) 1A formed by twisting leftward a piezoelectric thread having a circular section also generates a positive potential on the surface. Similarly, the S thread formed by winding rightward a piezoelectric thread having a circular section generates a negative potential on the surface. Such a thread may be simply a twisted thread without using a core thread. Such a thread can be made at low cost.

As described above, the polarization generation fiber generates a positive potential or a negative potential on the surface by external energy. Such a polarization generation fiber functions as a charging fiber that positively or negatively charges a substance passing close to the polarization generation fiber by a positive potential or a negative potential generated on the surface of the charging fiber. The charging filter provided with the charging fiber positively or negatively charges the substance passing through the charging filter. In the example of FIG. 1, the substance passing through the charging filter 5 is positively charged.

FIG. 7 is a partial sectional view of the charging filter 5 and the attraction filter 20. On a side of the attraction filter 20 where the charging filter 5 is not disposed, there is a fan (not illustrated) of the air purifier. The fan generates an air flow from the charging filter 5 towards the attraction filter 20. Therefore, the substances in the air (a substance 50 and a substance 50A in the drawing) move from the charging filter 5 toward the attraction filter 20.

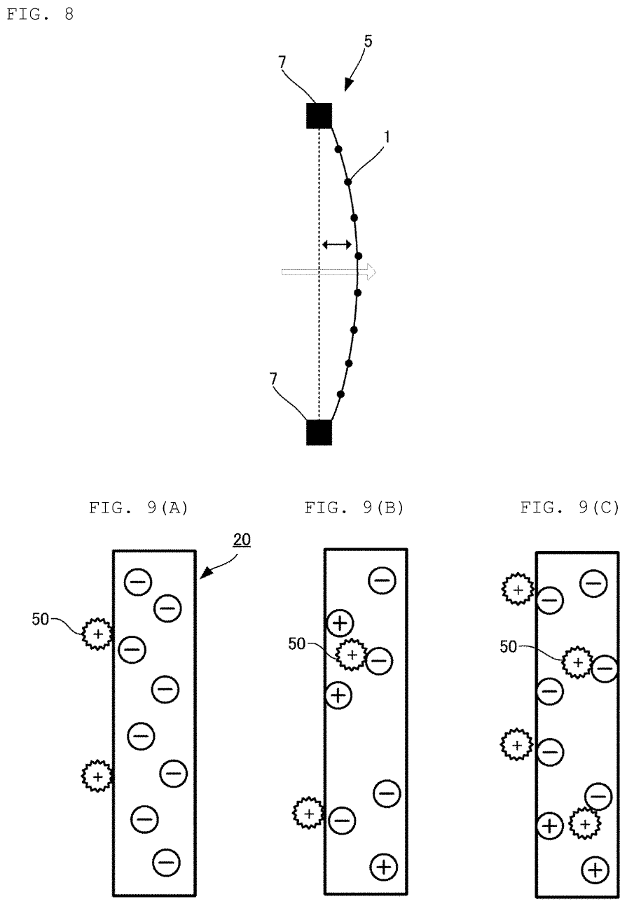

FIG. 8 is a sectional view of the charging filter 5. In the charging filter 5, the piezoelectric threads 1 are assembled in a lattice shape. Both ends of the piezoelectric thread 1 are fixed to the frame 7. In a case where there is no air flow, the piezoelectric thread 1 is in a state of being arranged in a straight line in the frame 7 as illustrated by a broken line in the drawing. When an air flow is generated, the piezoelectric thread 1 extends to expand in a direction along the air flow at a position farthest from the frame 7. Thereby, the piezoelectric thread 1 extends along the axial direction. Therefore, a positive potential is generated on the surface of the piezoelectric thread 1.

The air flow is not uniform. Therefore, the way that the piezoelectric thread 1 extends is not uniform and changes every moment. Therefore, the polarization generated in the piezoelectric thread 1 is not uniform. In addition, the stronger the air flow, the larger the amount of expansion of the piezoelectric thread 1, and thus the more polarization is generated.

The charging filter 5 captures the substance 50A that is larger than the a space between the piezoelectric threads 1 of the charging filter 5. Further, the piezoelectric thread 1 forming the charging filter 5 generates a positive potential on the surface by the piezoelectric film 10. Therefore, the charging filter 5 charges the substance 50 passing through the charging filter 5 to a positive potential. The substance 50 is charged to the same potential (positive potential) as the surface of the charging filter 5 by coming into contact with the charging filter 5. Alternatively, in a case where the charging filter 5 has a potential that is high enough to release charges into the air, the substance 50 is charged to the same potential (positive potential) by approaching the surface of the charging filter 5 even without coming into contact with the surface of the charging filter 5.

The substance 50 that has passed through the charging filter 5 reaches the attraction filter 20 at a subsequent stage. Since the attraction filter 20 is a HEPA filter having very fine openings, the attraction filter 20 captures the substance that has passed through the charging filter 5.

Further, the surface of the attraction filter 20 has a negative potential. The attraction filter 20 is made of, for example, a dielectric fiber (electret filter) of which the surface is polarized to a negative potential. Therefore, the substance 50 charged to a positive potential is attracted by the attraction filter 20 at the subsequent stage. Therefore, the substance attracting material 100 including the charging filter 5 and the attraction filter 20 exhibits a higher dust collection power than the HEPA filter alone. In addition, the stronger the air flow, the more polarization is generated, and therefore the charging filter 5 exhibits higher dust collection power. Thus, it is suitable for the substance attracting material 100 to be used as a filter of the air purifier.

Note that, in the above-described example, the example in which the attraction filter 20 is an electret filter of which the surface is negatively polarized is illustrated. However, for example, even in case of the piezoelectric thread 3 illustrated in FIG. 5, a negative potential is generated, and thus the function of the attraction filter 20 can be realized.

In the electret filter, when a substance having a potential of the opposite polarity is attracted, the potential on the surface of the electret filter is neutralized. Therefore, the attraction power may be decreased as the amount of attracting substances is increased. On the other hand, in case of using a piezoelectric fiber such as the piezoelectric thread 1 or the piezoelectric thread 3, even if the amount of attracting substances is increased, the generated potential does not change, so that the attraction power is not decreased.

In addition, as described above, when air flows, the way that the piezoelectric thread 1 and the piezoelectric thread 3 extend is not uniform and changes from moment to moment. Therefore, the polarization generated on the surface of the piezoelectric thread 1 is not uniform, and a negative potential of the opposite polarity may be generated. Similarly, a positive potential may be generated in the piezoelectric thread 3. Therefore, the surface potential of the attraction filter 20 using the piezoelectric thread 1 or the piezoelectric thread 3 may be positive or negative. For example, after the attraction filter 20 has attracted the substance 50 charged to a positive potential as illustrated in FIG. 9(A), the potential of the surface of the attraction filter 20 may become positive at a certain portion as illustrated in FIG. 9(B). In this case, the substance 50 having been attracted to the surface is repelled, and is attracted to a portion of the attraction filter 20 where a negative potential is generated. Thereafter, as illustrated in FIG. 9(C), when the potential of the surface of the attraction filter 20 becomes negative, a substance having a positive potential can be attracted again. As described above, even if the amount of attracted substances increases, the possibility that the attraction power decreases is low in the attraction filter 20 using the piezoelectric thread 1 or the piezoelectric thread 3.

The example has been described above in which the charging filter 5 at a preceding stage generates a positive potential and the attraction filter 20 at the subsequent stage generates a negative potential. However, of course, a configuration in which the charging filter 5 at the preceding stage generates a negative potential to negatively charge the substance and the attraction filter 20 at the subsequent stage generates a positive potential may be adopted.

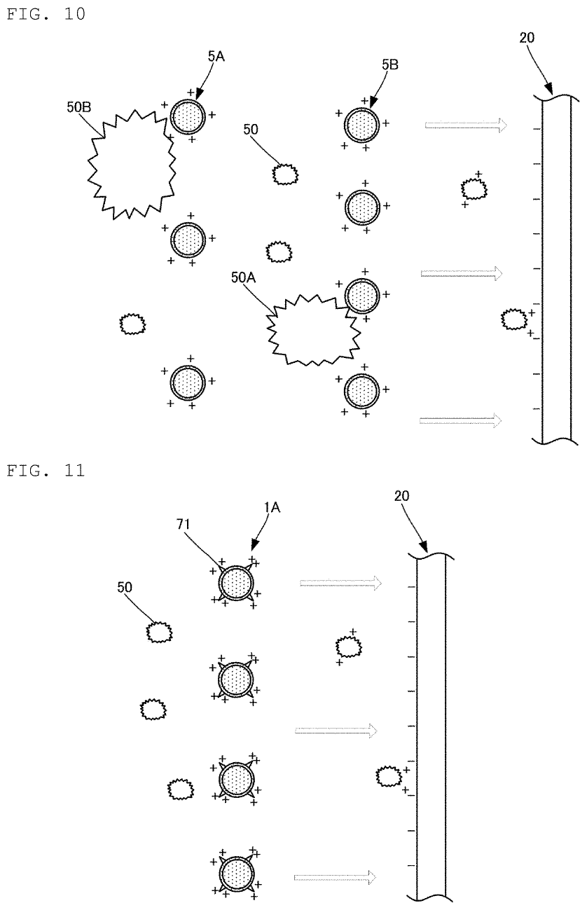

Further, the number of each of the charging filter 5 and the attraction filter 20 need not be one. For example, as illustrated in FIG. 10, a first charging filter 5A having relatively large openings may be disposed at the preceding stage, and a second charging filter 5B having relatively fine openings may be disposed at the subsequent stage. In this case, a substance 50B that is larger than the opening of the first charging filter 5A is captured by the first charging filter 5A at the preceding stage. Since the substance 50B does not reach the second charging filter 5B, the second charging filter 5B can prevent clogging. Further, even if the substance 50B passes through the first charging filter 5A, the substance 50B is reliably charged.

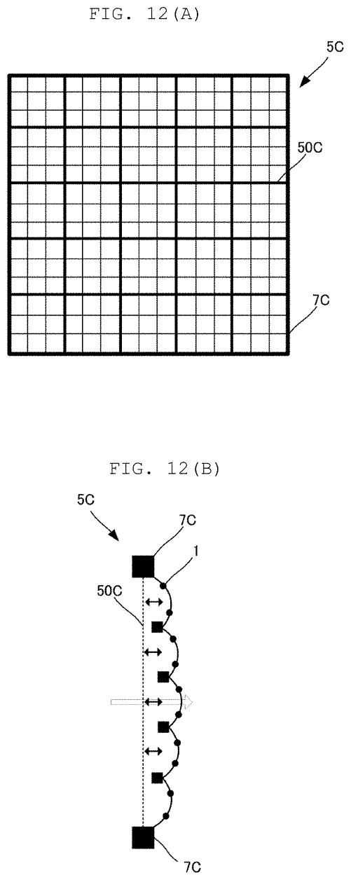

Next, FIG. 11 is a partial sectional view of the piezoelectric thread 1A including an electrode 71 and the attraction filter 20. The piezoelectric thread 1A generates a positive potential on the surface similarly to the piezoelectric thread 1, but further includes the electrode 71 on the surface. The shape of the electrode 71 is, for example, a needle shape as illustrated in FIG. 11. However, the shape of the electrode 71 is not limited to this example. The electrode 71 may have a thin film shape that covers a part of the surface of the piezoelectric thread 1A. Since the electrode 71 is a conductor, positive polarization generated on the surface of the piezoelectric thread 1A is concentrated. Therefore, a locally high positive potential is generated on the surface of the electrode 71. Therefore, the transfer of charges to the substance 50 through the electrode 71 is more likely to occur. Alternatively, since a higher potential is generated on the electrode 71, there is a possibility that a potential that is high enough to release charges into the air is generated. Therefore, the substance 50 approaches the surface of the charging filter 5 and is easily charged to the same potential (positive potential) even without coming into contact with the surface of the charging filter 5.

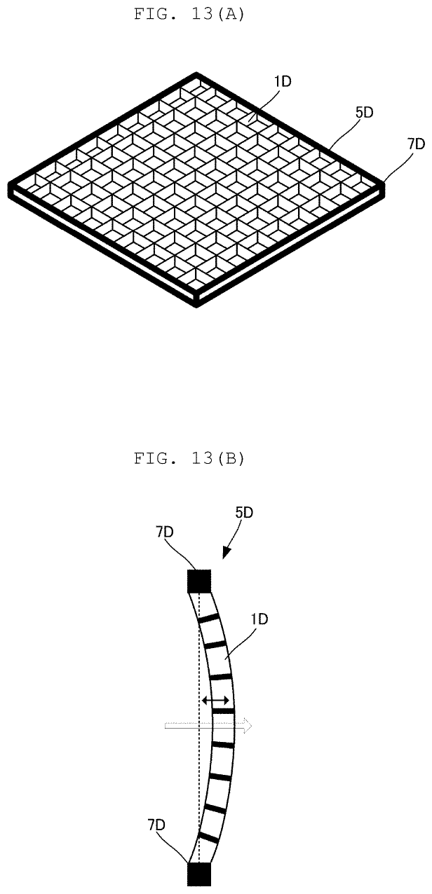

FIG. 12(A) is a plan view of a charging filter 5C according to Modification Example 1. FIG. 12(B) is a sectional view of the charging filter 5C. A frame 7C includes a partition member 50C that partitions the inner side of the frame 7C in a lattice shape in a plan view. Both ends of each of the plurality of piezoelectric threads 1 are fixed to the partition member 50C (or the frame 7C).

The partition member 50C has a smaller sectional area than the frame 7C. Further, the partition member 50C is made of a material softer than the frame 7C. Therefore, as illustrated in FIG. 12(B), when an air flow is generated, the partition member 50C extends to expand in a direction along the air flow at a position farthest from the frame 7C. Then, the plurality of piezoelectric threads 1 extend to expand toward the direction along the air flow between both ends of the partition member 50C (or the frame 7C). As a result, each of the piezoelectric threads 1 undergoes the same degree of deformation. Therefore, a positive potential having uniform strength is generated on the surface of the piezoelectric thread 1 as a whole.

Note that the partition member 50C may be made of metal (conductor). In case of a conductor, the charges generated in each piezoelectric thread 1 are transferred to the partition member 50C, and a more uniform potential is generated as a whole. Further, in Modification Example 1, the piezoelectric thread generates a positive potential, but may generate a negative potential.

FIG. 13(A) is a perspective view of a charging filter 5D according to Modification Example 2. FIG. 13(B) is a sectional view of the charging filter 5D. In the charging filter 5D, a plurality of piezoelectric sheets 1D are arranged in a lattice shape in a frame 7D. Both ends of each of the piezoelectric sheets 1D are fixed to the frame 7D. The piezoelectric sheet 1D has a certain width along the direction in which air flows. Also in this case, as illustrated in FIG. 13(B), when an air flow is generated, the plurality of piezoelectric sheets 1D extend to expand in a direction along the air flow.

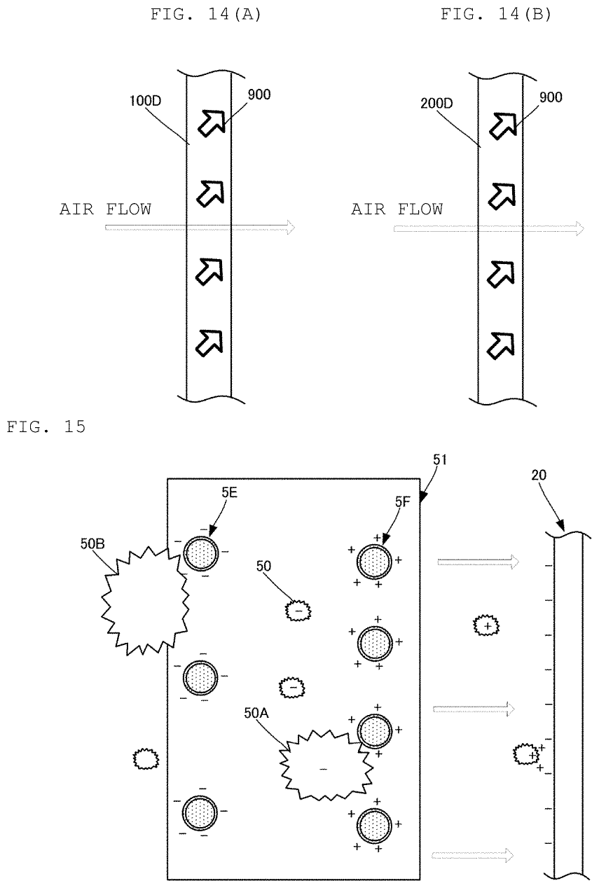

FIG. 14(A) is a plan view of the piezoelectric sheet 1D as viewed in plan, and FIG. 14(B) is a rear view. In the piezoelectric sheet 1D, a first piezoelectric sheet 100D and a second piezoelectric sheet 200D are bonded. The first piezoelectric sheet 100D is stretched while being inclined 45 degrees to the right with respect to the direction in which air flows. Further, the second piezoelectric sheet 200D is also stretched while being inclined 45 degrees to the right with respect to the direction in which air flows. Therefore, the piezoelectric sheet 1D generates a positive potential on both the front surface and the rear surface.

In this case, since the piezoelectric sheet 1D has a width in the direction in which air flows, the area of the piezoelectric sheet 1D at which the piezoelectric sheet 1D comes into contact with substances is larger than the area of the piezoelectric thread at which the piezoelectric thread comes into contact with substances. Therefore, the piezoelectric sheet 1D easily charges substances.

Note that a configuration may be adopted such that the charging fiber is formed of a piezoelectric fiber that generates a negative potential on the surface (for example, S thread of PLLA) and a piezoelectric fiber that generates a positive potential on the surface (for example, Z thread of PLLA). For example, the charging filter 51 of FIG. 15 includes a first charging filter 5E and a second charging filter 5F. The first charging filter 5E generates a negative potential. The second charging filter 5F generates a positive potential.

In this case, the substance 50B that is larger than the openings of the first charging filter 5E is captured by the first charging filter 5E at the preceding stage. The substance 50 and the substance 50A passing through the first charging filter 5E are charged to a negative potential. Therefore, the substance 50 and the substance 50A passing through the first charging filter 5E are more likely to be attracted by the second charging filter 5F at the subsequent stage. Further, even if the substance 50B passes through the first charging filter 5E, the substance 50B becomes in a negatively charged state and thus is easily attracted by the second charging filter 5F. Then, the substance 50 that has not been completely attracted by the second charging filter 5F is charged to a positive potential. Therefore, the substance 50 that has passed through the second charging filter 5F is attracted by the attraction filter 20 at the subsequent stage.

In the example of FIG. 15, a piezoelectric fiber that generates a negative potential is disposed at the preceding stage and a piezoelectric fiber that generates a positive potential is disposed at the subsequent stage. However, a piezoelectric fiber that generates a positive potential may be disposed at the preceding stage, and a piezoelectric fiber that generates a negative potential may be disposed at the subsequent stage. In this case, as the attraction filter 20, a piezoelectric fiber that generates a positive potential or an electret filter of which the surface is polarized to a positive potential is used.

Further, both a piezoelectric fiber that generates a positive potential and a piezoelectric fiber that generates a negative potential may be disposed in one charging filter. That is, the charging fiber of the present invention may be a piezoelectric fiber having both the first piezoelectric fiber that generates a negative potential and the second piezoelectric fiber that generates a positive potential.

In the above embodiment, the piezoelectric thread is illustrated as a fiber that generates polarization by external energy. However, as the fiber that generates an electric potential by external energy, there are also a substance having a photoelectric effect, a substance having a pyroelectric effect (for example, PVDF), a substance that generates a potential due to a chemical change, and the like. Further, a configuration in which a conductor is used as a core thread, an insulator is wound around the conductor, and polarization is generated by flowing electricity through the conductor is also a fiber that generates an electric potential, and unlike corona discharge, a large unit is not required.

In particular, since a piezoelectric body generates an electric field by piezoelectricity, a power supply is not necessary. Further, the life of the piezoelectric body is long, and there is no change in the amount of polarization due to the attracted substances. Therefore, the attraction power does not decrease as the amount of attracted substances increases, unlike in the case of the electret filter.

Finally, the description of the present embodiment is illustrative in all aspects and should be considered as non-limiting. The scope of the present invention is indicated by the claims, rather than the above-described embodiments. Further, the scope of the present invention is intended to include all modifications within the meaning and scope equivalent to the claims.

### DESCRIPTION OF REFERENCE SYMBOLS

1, 1A, 3: piezoelectric thread

1D: piezoelectric sheet

5, 5C, 5D, 51: charging filter

5A, 5E: first charging filter

5B, 5F: second charging filter

7, 7C, 7D: frame

10: piezoelectric film

11: core thread

20: attraction filter

50, 50A, 50B: substance

50C: partition member

71: electrode

100: substance attracting material

1. A charging fiber arrangement comprising:
a pair of adjacent polarization generation fibers that each generate a positive potential or a negative potential on a surface thereof by input of external energy, wherein the pair of adjacent polarization generation fibers are arranged to positively charge a substance passing between the pair of adjacent polarization generation fibers by the positive potential, or negatively charge the substance passing between the pair of adjacent polarization generation fibers by the negative potential.

2. The charging fiber arrangement according to claim 1, wherein at least one of the pair of adjacent polarization generation fibers is a piezoelectric fiber that is wound with respect to an axial direction of the at least one of the pair of adjacent polarization generation fibers.

3. The charging fiber arrangement according to claim 2, wherein the at least one of the pair of adjacent polarization generation fibers generates the positive potential or the negative potential by extension and contraction in the axial direction.

4. The charging fiber arrangement according to claim 1, wherein the at least one of the pair of adjacent polarization generation fibers generates the positive potential or the negative potential by extension and contraction in the axial direction.

5. The charging fiber arrangement according to claim 2, wherein the piezoelectric fiber is wound leftward with respect to the axial direction and generates the negative potential by extension and contraction in the axial direction.

6. The charging fiber arrangement according to claim 2, wherein the piezoelectric fiber is wound rightward with respect to the axial direction and generates the positive potential by extension and contraction in the axial direction.

7. The charging fiber arrangement according to claim 1, further comprising:
a conductor on the surface of at least one of the pair of adjacent polarization generation fibers.

8. A charging filter comprising the charging fiber arrangement according to claim 1.

9. The charging filter according to claim 8, wherein at least one of the pair of adjacent polarization generation fibers is a piezoelectric fiber that is wound with respect to an axial direction of the at least one of the pair of adjacent polarization generation fibers.

10. The charging filter according to claim 9, wherein the at least one of the pair of adjacent polarization generation fibers generates the positive potential or the negative potential by extension and contraction in the axial direction.

11. The charging filter according to claim 8, wherein the at least one of the pair of adjacent polarization generation fibers generates the positive potential or the negative potential by extension and contraction in the axial direction.

12. The charging filter according to claim 9, wherein the piezoelectric fiber is wound leftward with respect to the axial direction and generates the negative potential by extension and contraction in the axial direction.

13. The charging filter according to claim 9, wherein the piezoelectric fiber is wound rightward with respect to the axial direction and generates the positive potential by extension and contraction in the axial direction.

14. The charging filter according to claim 8, further comprising:
a conductor on the surface of at least one of the pair of adjacent polarization generation fibers.

15. The charging filter according to claim 8, further comprising:
a frame, and wherein ends of the pair of adjacent polarization generation fibers are fixed to the frame.

16. The charging filter according to claim 15, wherein the frame includes a partition member that partitions an inner side of the frame in a lattice shape in a plan view of the charging filter.

17. A substance attracting material comprising:
the charging filter according to claim 8; and
an attraction filter that generates a potential having a polarity opposite to the potential generated by the pair of adjacent polarization generation fibers, and attracts the substance having passed between the pair of adjacent polarization generation fibers.

18. The substance attracting material according to claim 17, wherein the charging filter is a first charging filter, and the substance attracting material further comprises:
a second charging filter between the first charging filter and the attraction filter, the second charging filter including a second pair of adjacent polarization generation fibers that each generate a potential on a surface thereof the same as that of the first charging filter by input of external energy, and wherein the second pair of adjacent polarization generation fibers are arranged to charge a substance passing therebetween by the same potential as that of the first charging filter.

19. The substance attracting material according to claim 17, wherein the charging filter is a first charging filter, and the substance attracting material further comprises:
a second charging filter between the first charging filter and the attraction filter, the second charging filter including a second pair of adjacent polarization generation fibers that each generate a potential on a surface thereof opposite to that of the first charging filter by input of external energy, and wherein the second pair of adjacent polarization generation fibers are arranged to charge a substance passing therebetween by the opposite potential as that of the first charging filter.

20. An air purifier comprising:
the substance attracting material according to claim 17.
